(19) United States
(12) Patent Application Publication
(10) Pub. No.: US 2016/0379800 A1
(43) Pub. Date: Dec. 29, 2016

(54) PLASMA ETCHING METHOD AND METHOD OF MANUFACTURING PATTERNED SUBSTRATE

(71) Applicant: FUJIFILM Corporation, Tokyo (JP)

(72) Inventor: Akihiko OHTSU, Ashigarakami-gun (JP)

(73) Assignee: FUJIFILM Corporation, Tokyo (JP)

(21) Appl. No.: 15/258,443

(22) Filed: Sep. 7, 2016

Related U.S. Application Data
(63) Continuation of application No. PCT/JP2015/001184, filed on Mar. 5, 2015.

(30) Foreign Application Priority Data
Mar. 11, 2014 (JP) 2014-047028

(51) Int. Cl. H01J 37/32

(52) U.S. Cl. CPC H01J 37/32009; H01J 37/32715; H01J 2237/334

(57) ABSTRACT

When a mask pattern provided on a dielectric substrate is provided with a pattern area having a plurality of micro openings, and a non-pattern area other than the pattern area, in the case in which the dielectric substrate is mounted at a predetermined position in a substrate mounting structure portion, in the pattern area, the configuration of the substrate mounting structure portion is set such that an average dielectric constant between a surface of the dielectric substrate and a surface of a predetermined electrode of the substrate mounting structure portion is larger than an average dielectric constant in the non-pattern area, and the dielectric substrate is etched by mounting the dielectric substrate at the predetermined portion of the substrate mounting structure portion, and generating plasma under an atmosphere reduced in pressure compared with atmospheric pressure.

### CROSS-REFERENCE TO RELATED APPLICATIONS

This application is a Continuation of PCT International Application No. PCT/JP2015/001184 filed on Mar. 5, 2015, which claims priority under 35 U.S.C. §119(a) to Japanese Patent Application No. 2014-047028 filed on Mar. 11, 2014. Each of the above applications is hereby expressly incorporated by reference, in its entirety, into the present application.

### BACKGROUND OF THE INVENTION

1. Field of the Invention

The present invention relates to a plasma etching method and a method of manufacturing a patterned substrate.

2. Description of the Related Art

Nanoimprinting is a technique of pressing a mold (also generally referred to as a mold, a stamper, or a template), on which an uneven pattern is formed, against a resist coated on an object to be processed so that the resist is caused to mechanically deform or to flow, to precisely transfer a fine pattern. If a mold is produced once, nano-level fine structures can be repeatedly molded in a simple manner. Therefore, the nanoimprinting method is an economical transfer technique that produces very little harmful waste and discharge. Thus, in recent years, there have been high expectations with regard to application of the nanoimprinting method in various fields.

Regarding a nanoimprint template, from the viewpoint of solving various problems in a nanoimprint lithography process (more specifically, from the viewpoint of the convenience of a contact process and the inhibition of resist-unfilled defects), the use of a template, the rear surface of which is subjected to counterboring processing (recessed portion), has become the industrial standard.

When a nanoimprint template for semiconductor lithography is manufactured, a nanoimprint template having excellent in-plane shape uniformity in etching at a high throughput, which is equal to or higher than that of the conventional photomask, with respect to a template substrate in which the rear surface is subjected to recess processing, which has not been used conventionally, is required.

In the case in which a plurality of copy templates are produced from one master disk (mold), the copy templates are obtained by forming a hard mask layer on a substrate of quartz or the like, forming a resist pattern on the hard mask layer, etching the hard mask layer using the resist pattern as a mask to form a hard mask pattern, and then etching the hard mask pattern to form an uneven pattern on the surface of the substrate.

When such an etching treatment is carried out, normally, etching is carried out by applying an etching bias to a lower electrode provided below the mounting portion of a substrate in an etching apparatus. At this time, the irradiation energy of the etching ions is heavily dependent on the potential of the upper surface of the substrate at the time of etching.

As the aforementioned substrate having the counterbore portion (recessed portion), a substrate having a size of 6 inches square and a thickness of 6.35 mm is frequently used and this substrate is significantly thicker compared to a Si wafer (having a thickness of about 0.65 mm to 0.75 mm) that is used for device manufacturing. Due to the thickness, the surface potential increases and as a result, the ion irradiation energy to be obtained decreases. Particularly, the electrostatic capacity in the recessed portion decreases and as a result, the ion energy decreases. The etching rate is proportional to the ion energy and the etching rate decreases along with a decrease in the ion energy. That is, the in-plane uniformity at an etching rate cannot be maintained.

As means for eliminating in-plane non-uniformity at an etching rate, for example, in JP2013-206971A, a method of making the in-plane distribution of the electrostatic capacity and (or) the in-plane distribution of the temperature in an area including a template substrate uniform by backfilling of a counterbore portion (recessed portion) in the template substrate is proposed.

In addition, in JP2013-42160A, a method of compensating for etching non-uniformity between the center and the peripheral edge portion of a substrate by providing two gas filling openings is proposed and in JP2003-506889A, a method of compensating for process in-plane non-uniformity by arranging a solid having an uneven surface sectional shape or a gaseous dielectric layer below the wafer is proposed.

### SUMMARY OF THE INVENTION

However, in the method of JP2013-206971A, non-uniformity in the etching shape (side wall angle) is not eliminated in the pattern area immediately above the recessed portion.

In the method of JP2013-42160A, there is a problem of a significant increase in apparatus costs since the chamber itself needs to be improved and the like.

Further, in JP2003-506889A, in the case in which the pattern area is present in only a part of the wafer, there are problems in that shape non-uniformity is generated in the shape after etching (side wall angle and the like) in the pattern area, and the defect density (DD) significantly increases in repeated processes.

Among these problems, the problems of non-uniformity in the side wall angle and an increase in the defect density will be described in detail using FIGS. 17 to 21.

FIGS. 17 to 19 are schematic views for illustrating non-uniformity in etching shape, which is the first problem, and FIG. 17 is a schematic cross-sectional view showing the inside of an etching apparatus.

A substrate 50 which is an object to be etched is a substrate having a counterbore portion (recessed portion) 51 on the rear surface and the surface thereof is composed of a B area in which a mask pattern 55, which is arranged on the counterbore portion 51, is present (hereinafter, referred to as a pattern area B), and an A area in which the mask pattern is not present (hereinafter, referred to as a non-pattern area A). In a 6 inches square quartz substrate (having a thickness of 6.35 mm) which is the most orthodox substrate specification as a nanoimprint template, the center portion diameter φ of the recess area is 64 mm and an uneven pattern is formed in an area corresponding to the recessed portion.

In the etching apparatus proposed in JP2013-206971A, as shown in FIG. 17, a substrate mounting structure portion 120 in which a dielectric member 126 having the same dielectric constant as the dielectric constant of a substrate having a shape corresponding to the shape of the counterbore portion of the substrate 50 is arranged on a substrate mounting portion 114 on which the substrate 50 is mounted and below which a lower electrode 112 is provided is provided. The substrate 50 is arranged on the substrate mounting portion 114 and plasma etching by radicals and ions X⁺is carried out from the upper surface side thereof. In the drawing, the radicals are omitted.

In this manner, since a uniform electrostatic capacity can be achieved over the entire area of the substrate, it is considered that the etching rate becomes uniform. However, at the time of etching, an etching (volatilization) product is disassociated and deposited again in some cases. Thus, a larger amount of the etching (volatilization) product is produced in the non-pattern area A in which a resist pattern is not formed (which is not covered with a mask and has an opening ratio of 100%) than in the pattern area B. Therefore, a deposit is highly likely to adhere to a portion of the area B closer to the area A and the pattern shape after etching is affected by the etching product in some cases. That is, from the investigation conducted by the present inventor, it has been found that as shown in the partially enlarged view of FIG. 17, non-uniformity in the pattern shape, particularly, the pattern side wall angle (side wall rising angle) between the pattern center portion and the boundary area, which is close to the area A, in the area B is generated and as a result, there is a concern of non-uniformity in the pattern shape in the area B (specifically, pattern side wall angle) being generated.

The mechanism of generating non-uniformity in the pattern side wall angle will be described with reference to FIG. 18. FIG. 18 is an enlarged view of an area in which one projecting portion of the mask pattern 55 is set as the center. As shown in FIG. 18, the deposit derived from the etching gas or the etching product is deposited on the surface of the etched surface. FIG. 18 shows the case in which etching and deposition compete with each other, and in this case, etching and deposition of the deposit on the surface occur alternately. In fact, deposition and etching simultaneously occur and thus the side wall 52 of the projecting portion is formed into a smoothly tapered shape.

On the other hand, FIG. 19 shows a state in which etching and deposition of a deposit on the surface occur alternately in the case in which the amount of the deposit to be generated increases. In the case in which the amount of deposition further increases, the side wall angle θ₂ of the side wall 52 of the projecting portion is smaller than the side wall angle θ₁ at the time of competition shown in FIG. 18.

FIGS. 20 and 21 are schematic view for illustrating the generation of a defective pattern, which is the second problem, and FIG. 20 is a schematic cross-sectional view showing the inside of an etching apparatus.

The substrate 50 which is an object to be etched is a substrate having the counterbore portion (recessed portion) 51 on the rear surface and the surface thereof is composed of a pattern area B in which the mask pattern 55, which is arranged on the counterbore portion 51, is present, and a non-pattern area A which is covered with a mask layer.

In the example shown in FIG. 17, a mask layer is not formed in the area A. However, in this example, the area A is covered with a mask layer and thus the area A is not etched. However, as shown in (a) of FIG. 21, actually, ions are radiated with high energy and thus physical etching is carried out on the mask layer, which causes the etching product 56 to scatter. In addition, since the non-pattern area A has a large area compared to the pattern area B, the amount of the etching product 56 produced in the area A is considerable. First, there is a concern of pattern defects being generated due to direct adhesion of this etching product 56 to the pattern of the area B. In addition, the etching product 56 contaminates the inner wall of a chamber 101 ((b) of FIG. 21), due to accumulating on the inner wall of the chamber and at the time of the next etching treatment for another substrate to be treated, the etching product (contaminants) 56 thereof scatter and adhere to the substrate ((c) of FIG. 21). Thus, there is a concern of pattern defects being generated.

Incidentally, in the case in which a mask is provided in the non-pattern area and an etching product is produced from the mask, the amount of the etching product that cannot be removed as a volatilization product is larger than in the case in which a mask is not formed in the non-pattern area, and thus the generation of pattern defects caused by the etching product from the non-pattern area is more severe.

In order to inhibit the generation of defects caused by the contaminants produced in the chamber in such an etching treatment, the operational effort of carrying out a plasma cleaning treatment in every etching treatment and the like is required. However, adding a cleaning treatment in every treatment causes a significant decrease in a production speed and thus is not preferable.

The present invention is made in consideration of the above problems and an object thereof is to provide an etching method and apparatus capable of inhibiting non-uniformity in the pattern shape and defect generation at the time of etching and carrying out a treatment at a high throughput.

Further, another object of the present invention is to provide a method of manufacturing a patterned substrate having high uniformity in the pattern shape, a small number of defects, and high productivity.

A plasma etching method of the present invention is a method of carrying out plasma etching on a dielectric substrate provided with a mask pattern on a surface side, the method comprising:

when the mask pattern provided on the dielectric substrate includes a pattern area having a plurality of micro openings and a non-pattern area other than the pattern area,

in a case in which the dielectric substrate is mounted at a predetermined position in a substrate mounting structure portion including a predetermined electrode in a plasma etching apparatus, setting a configuration of the substrate mounting structure portion such that an average dielectric constant between the surface of the dielectric substrate and a surface of the predetermined electrode of the substrate mounting structure portion in the pattern area is larger than the average dielectric constant in the non-pattern area;

mounting the dielectric substrate at the predetermined position on the substrate mounting structure portion; and

generating plasma under an atmosphere reduced in pressure compared with atmospheric pressure to etch the dielectric substrate.

In the plasma etching apparatus, the term “predetermined electrode” generally means the lower electrode arranged below the mounting portion on which the substrate is mounted and a negative bias voltage is induced with respect to the plasma.

As a method of making the average dielectric constant between the surface of the dielectric substrate and the surface of the predetermined electrode of the substrate mounting structure portion in the pattern area larger than the average dielectric constant in the non-pattern area, a method of setting the configuration of the substrate mounting structure portion such that a distance between the surface of the dielectric substrate and the surface of the predetermined electrode in the pattern area is shorter than the distance in the non-pattern area, and/or a method of setting the configuration of the substrate mounting structure portion such that the volume of a free space between the surface of the dielectric substrate and the surface of the predetermined electrode in the non-pattern area is larger than the volume of a free space between the surface of the dielectric substrate and the surface of the predetermined electrode in the pattern area can be adopted.

It is preferable that a mask material for the mask pattern is a nonconductor.

It is preferable that the dielectric substrate is a substrate having a counterbore portion at the center portion of the rear surface, and

the mask pattern has the pattern area in at least a part of an area corresponding to the counterbore portion of the dielectric substrate, and an area not corresponding to the counterbore portion of the dielectric substrate is the non-pattern area.

A method of manufacturing a patterned substrate of the present invention comprises:

sequentially depositing a hard mask layer and applying a resist layer on a surface of a substrate to be processed;

forming a plurality of micro openings on the resist layer to form a resist pattern; etching the hard mask layer using the resist pattern as a mask to form a hard mask pattern; and etching the substrate to be processed using the hard mask pattern as a mask to manufacture a patterned substrate,

wherein the plasma etching method of the present invention is used during the etching of the hard mask layer and/or the etching of the substrate to be processed.

According to the plasma etching method of the present invention, since when a dielectric substrate on which a mask pattern provided with a pattern area having a plurality of micro openings on the surface and a non-pattern area other than the pattern area is formed is subjected to plasma etching, in the case in which the dielectric substrate is mounted at a predetermined position in a substrate mounting structure portion including a predetermined electrode in a plasma etching apparatus, the configuration of the substrate mounting structure portion is set such that the average dielectric constant between the surface of the dielectric substrate and the surface of the predetermined electrode of the substrate mounting structure portion in the pattern area is larger than the average dielectric constant in the non-pattern area, the etching rate in the pattern area can made higher than the etching rate in the non-pattern area. Accordingly, it is possible to inhibit the production of an etching product from the non-pattern area at the time of etching, and to inhibit contamination of the pattern area by the etching product from the non-pattern area, adhesion of the product to the wall surface of the treatment container of the etching apparatus, and the like. As a result, it is possible to enhance pattern uniformity and to inhibit the generation of defects in the pattern area of the dielectric substrate. In addition, since the frequency of cleaning of the treatment container of the etching apparatus can be reduced, an etching treatment can be carried out at a high throughput.

In addition, according to the method of manufacturing a patterned substrate of the present invention, since the above etching method of the present method is used, it is possible to obtain a patterned substrate having high uniformity in the pattern shape, a small number of defects, and high productivity.

### BRIEF DESCRIPTION OF THE DRAWINGS

FIG. 1 is a view showing a process of a method of manufacturing a patterned substrate using an etching method of the present invention.

FIG. 2 schematically shows a plan view (A) and a cross-sectional view (B) of a template substrate.

FIG. 3 is a view showing a process of forming a resist pattern on the template substrate by a nanoimprinting method.

FIG. 4 is a view showing a schematic configuration of an embodiment of an etching apparatus for implementing the etching method of the present invention.

FIG. 5 is view for illustrating a first configuration example of a substrate mounting structure portion of the etching apparatus for illustrating the etching method of the present invention.

FIG. 6 is a schematic view showing a second configuration example of the substrate mounting structure portion.

FIG. 7 is a schematic view showing a third configuration example of the substrate mounting structure portion.

FIG. 8 is a schematic view showing a fourth configuration example of the substrate mounting structure portion.

FIG. 9 is a schematic view showing a fifth configuration example of the substrate mounting structure portion.

FIG. 10 is a schematic view showing a sixth configuration example of the substrate mounting structure portion.

FIG. 11 is a schematic view showing a seventh configuration example of the substrate mounting structure portion.

FIG. 12 is a schematic view showing an eighth configuration example of the substrate mounting structure portion.

FIG. 13 is a schematic view showing a ninth configuration example of the substrate mounting structure portion.

FIG. 14 is a schematic view showing a tenth configuration example of the substrate mounting structure portion.

FIG. 15 is a schematic view showing an eleventh configuration example of the substrate mounting structure portion.

FIG. 16 is a schematic view showing a configuration of a substrate mounting structure portion in Comparative Example 1.

FIG. 17 is a schematic view for illustrating the first problem of the related art.

FIG. 18 is a view showing a projecting portion side surface having a tapered shape due to repeatedly carrying out etching and deposition.

FIG. 19 is a view showing a projecting portion side surface having a tapered shape due to repeatedly carrying out etching and deposition.

FIG. 20 is a schematic view for illustrating the second problem of the related art.

FIG. 21 is a view for illustrating contamination in a treatment container due to etching and re-adhesion of contaminants to a substrate.

FIG. 22 is a plan view schematically showing a pedestal portion on which a pattern area is formed.

### DESCRIPTION OF THE PREFERRED EMBODIMENTS

Hereinafter, embodiments of the present invention will be described using the drawings. However, the present invention is not limited to the embodiments. Note that the scale of each constituent element in the drawings is changed as appropriate from the actual dimensions thereof, in order to facilitate visual recognition thereof.

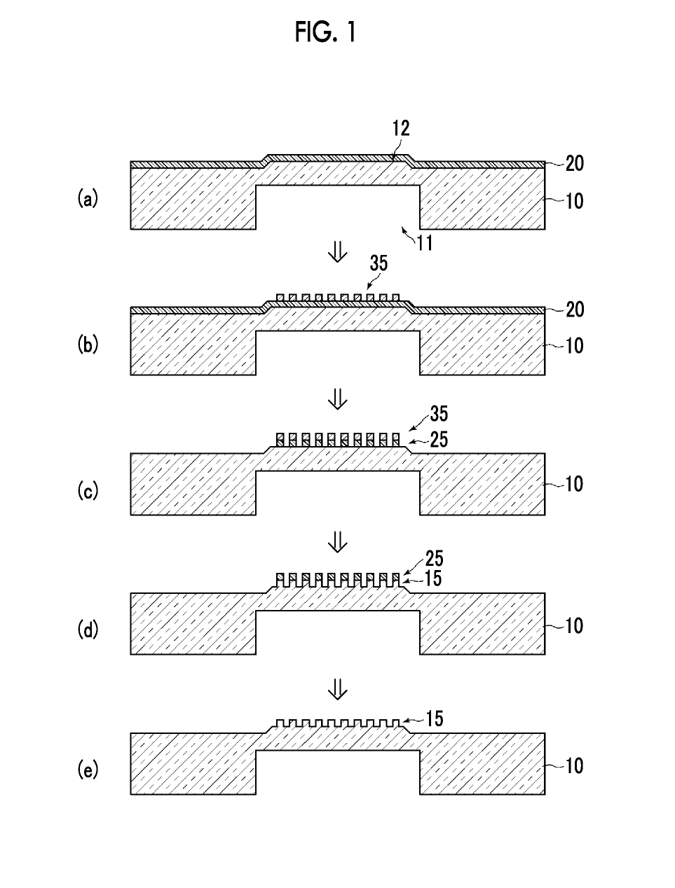

A method of manufacturing a patterned substrate having an uneven pattern on the surface including an etching process using a plasma etching method of the present invention will be described. FIG. 1 is a view schematically showing a process of manufacturing a patterned substrate. As shown in FIG. 1, a method of manufacturing a patterned substrate in the embodiement of the present invention includes, first, forming a hard mask layer 20 on a template substrate 10 ((a) of FIG. 1), forming a resist pattern 35 on the hard mask layer 20 ((b) of FIG. 1), then etching the hard mask layer 20 using the resist pattern 35 as a mask to form a hard mask pattern 25 ((c) of FIG. 1), etching the substrate 10 using the hard mask pattern 25 as a mask ((d) of FIG. 1), and finally removing the hard mask pattern 25 to obtain a patterned substrate ((e) of FIG. 1).

First, the template substrate will be described.

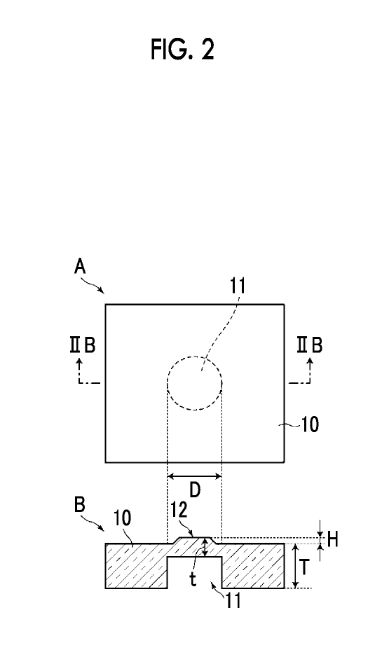

(Template Substrate) FIG. 2 schematically shows a plan view A and a cross-sectional view B of the template substrate 10. The template substrate 10 used in the embodiment is a dielectric having light transmittance and can be appropriately selected dispending on the purpose. Regarding the size and the structure thereof, a square shape with a size of a reticle used in semiconductor lithography, such as 65 mm×65 mm, 5 inches×5 inches, 6 inches×6 inches, or 9 inches×9 inches, is used and a circular counterbore portion 11 formed in the center of the rear surface is selected. The shape of counterboring processing is determined in consideration of permeability of gas, and a degree of flexure (bending rigidity) in a thinned portion of a substrate by counterboring processing. For example, a substrate having a size of 6 inches×6 inches, a substrate thickness T of 6.35 mm, a counterbore diameter D of 63 mm, and a remaining thickness t of the counterbore portion of 1.1 mm can be used.

It is preferable that the substrate 10 is provided with a pedestal portion 12 that is provided higher than other areas by a step difference H in a surface area corresponding to the counterbore portion 11. The substrate 10 may be flat over the entire surface without the pedestal portion 12. However, as long as the substrate is provided with the pedestal portion 12 and the a template having an uneven pattern in the pedestal portion 12 is produced, when being used in a device manufacturing process, an area of the template which is in contact with a wafer can be limited to the surface of the pedestal portion (mesa) 12 and thus a contact with a structure present in an area other than the patter formed area in the template can be avoided. The height (step difference) H of the pedestal portion 12 is preferably 1 μm to 1,000 μm, more preferably 10 μm to 500 μm, and even more preferably 20 μm to 100 μm.

(Method of Forming Hard Mask Layer)

The hard mask layer can be formed by a vapor phase film forming method, more specifically, a sputtering method, a chemical vapor deposition method, a molecular beam epitaxy method, an ion beam sputtering method, and the like.

The material for the hard mask layer is selected such that the etching selectivity of the hard mask layer with respect to a resist layer, which will be described later, in the etching of the hard mask layer is high, and the etching selectivity of the hard mask layer with respect to the substrate in the etching of the substrate is low. It is preferable that the material for the hard mask layer particularly include metal materials of Cr, W, Ti, Ni, Ag, Pt, Au, and the like, and metal oxide materials of CrOₓ, WO₂, TiO₂, and the like. However, when the method of the present invention is implemented, it is preferable to use a non-conductive material (nonconductor) for the hard mask layer. Herein, the term “non-conductive material” refers to a semiconductor or an insulating material. When the hard mask layer is present in only the pattern area, the hard mask layer may be formed with a conductor.

In consideration of the case in which a resist pattern is formed by an UV nanoimprinting method using a master template (mold) of Si or the like through which UV light hardly passes, the transmittance of the hard mask layer with respect to light having a wavelength in the vicinity of 365 nm is preferably 30% or more, more preferably 50% or more, and even more preferably 70% or more. The thickness of the hard mask layer is appropriately selected in consideration of the depth of target processing, the etching selectivity, and the transmittance of the finally obtained substrate. The thickness thereof is normally about 1 nm to 30 nm.

(Method of Forming Resist Pattern)

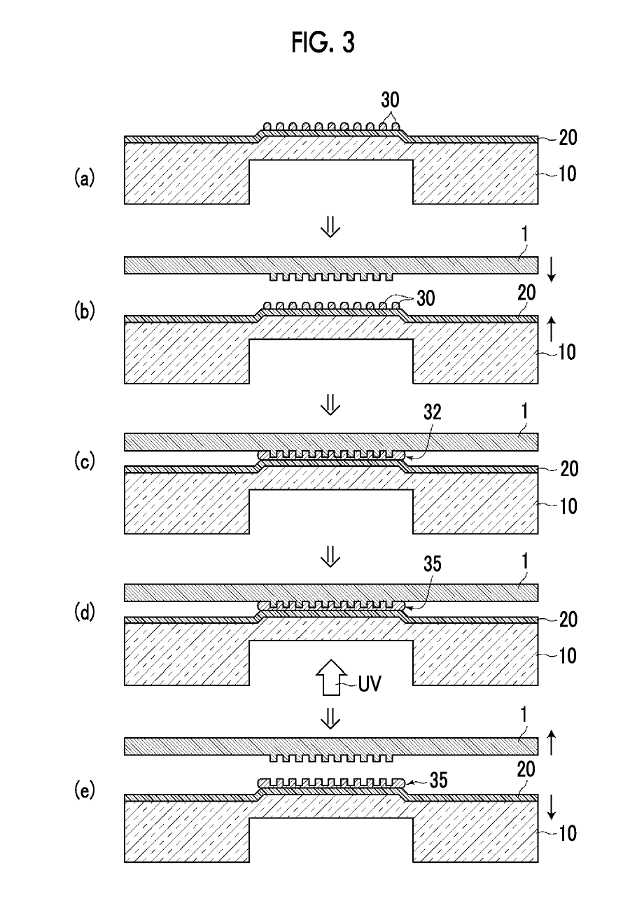

In the embodiement, the resist pattern 35 can be formed by a nanoimprinting method, a photolithography method, an electron beam lithography method, and the like. Herein, a method of forming the resist pattern 35 by a nanoimprinting method will be described. FIG. 3 is a view schematically showing a process of forming the resist pattern 35 by a nanoimprinting method. The method of forming the resist pattern by the nanoimprinting method includes, in this order, a process of applying a resist solution 30 to the hard mask layer 20 that is formed on the template substrate 10 ((a) of FIG. 3), a pressurization process of causing a master template (mold) 1 to be in contact with the surface of the substrate to be processed to which the resist solution 30 is applied and pressing the master template against the surface ((b) and (c) of FIG. 3), a curing process of curing a resist solution film 32 to form a resist pattern 35 ((d) of FIG. 3), and a release process of releasing the mold 1 from the cured resist pattern 35 having an uneven pattern shape ((e) of FIG. 3). Each process will be described below.

<Resist Solution Application Process>

First, the resist solution 30 to be used will be described. The resist solution 30 is not particularly limited but, for example, a material prepared by adding a photopolymerization initiator (about 2% by mass) and a fluorine monomer (0.1% by mass to 1% by mass) to a polymerizable compound can be used. In addition, an antioxidant (about 1% by mass) may also be added as required. The resist solution obtained through the above procedure can be cured by ultraviolet light having a wavelength of 360 nm. When the solubility is poor, it is preferable that a small amount of acetone or ethyl acetate is added thereto to dissolve the components, and then the solvent is removed by distillation. Examples of the polymerizable compound include benzyl acrylate (VISCOAT #160, manufactured by Osaka Organic Chemical Industry Co., LTD.), ethyl carbitol acrylate (VISCOAT #190, manufactured by Osaka Organic Chemical Industry, Co., LTD.), polypropylene glycol diacrylate (ARONIX M-220, manufactured by TOAGOSEI Co., LTD.), and trimethylol propane PO denatured triacrylate (ARONIX M-310, manufactured by TOAGOSEI Co., LTD.) as well as a compound A represented by Structural Formula (1) below. In addition, examples of the photopolymerization initiator include alkyl phenone photopolymerization initiators such as 2-(dimethyl amino)-2-[(4-methylphenyl)methyl]-1-[4-(4-morpholinyl)phenyl]-1-butanone (IRGACURE 379, manufactured by Toyotsu Chemiplas K.K.). Further, examples of the fluorine monomer include a compound B represented by Structural Formula (2) below. Herein, the viscosity of the resist solution is preferably 8 cP to 20 cP and the surface energy of the resist layer after the resist solution is applied is preferably 25 mN/m to 35 mN/m.

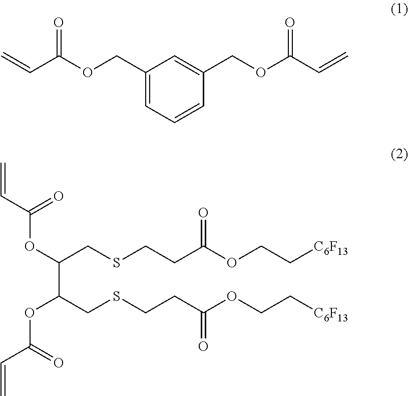

As the resist application method of applying the resist solution, a method capable of arranging a predetermined amount of liquid droplets to a predetermined position of a substrate or a mold, such as an ink jet method or a dispensing method, may be used. However, a method capable of applying a resist with a uniform film thickness, such as a spin coating method or a dip coating method, may be used. When liquid droplets are arranged on the substrate, an ink jet printer or a dispenser may be selectively used according to a desired amount of liquid droplets. For example, in the case in which the amount of liquid droplets is less than 100 nl (nanoliters), an ink jet printer is used, and in the case in which the amount of liquid droplets is 100 nl or more, a dispenser is used.

For an ink jet head which jets liquid droplets from nozzles, a piezoelectric type, a thermal type, an electrostatic type, and the like may be adopted. Among these, a piezoelectric type capable of adjusting the amount of liquid droplets (the amount per liquid droplet arranged) and the jetting rate is preferable. Before liquid droplets are arranged on the substrate, the amount of liquid droplets and the jetting rate are set and adjusted in advance. For example, it is preferable that the amount of liquid droplets is adjusted such that the amount of liquid droplets is large at a position on the substrate corresponding to an area in which the space volume of the uneven pattern of the mold is large and the amount of liquid droplets is small at a position on the substrate corresponding to an area in which the space volume of the uneven pattern of the mold is small. Such an adjustment can be controlled to be appropriate according to the amount of liquid droplets jetted (the amount per liquid droplet jetted). Specifically, in the case of setting the amount of liquid droplets to 5 pl (picoliters), the amount of liquid droplets is controlled by using an ink jet head having an amount of liquid droplets jetted of 1 pl such that the liquid droplets are jetted to the same place five times. The amount of liquid droplets is obtained by measuring the three-dimensional shape of the liquid droplets jetted on the substrate in advance under the same condition with a confocal microscope or the like and calculating the volume from the shape. After the amount of liquid droplets is adjusted as described above, the liquid droplets are arranged on the substrate according to a predetermined liquid droplet arrangement pattern. The liquid droplet arrangement pattern is constituted by two-dimensional coordinate information that includes lattice point groups corresponding to the liquid droplet arrangement on the substrate.

On the other hand, when a spin coating method or a dip coating method is used, the resist is diluted with a solvent so as to obtain a predetermined thickness and the number of rotations, in the case of using the spin coating method, and the pulling rate, in the case of using the dip coating method, are controlled. Thus, a uniform coating film may be formed on the substrate.

<Pressurization Process of Pressing Mold to Surface of Substrate to be Processed to which Resist Solution Applied>

Before the mold is brought into contact with the resist applied surface of the substrate having the hard mask layer of the substrate formed thereon and the resist solution applied thereto, the amount of residual gas is reduced by depressurizing the atmosphere between the mold and the substrate or causing the atmosphere between the mold and the substrate to be a vacuum. However, there is a possibility that the resist may volatilize before curing under a high vacuum atmosphere, causing difficulties in maintaining a uniform film thickness. Thus, it is preferable to reduce the amount of residual gas by causing the atmosphere between the mold and the substrate to be a He atmosphere or a depressurized He atmosphere. Since He passes through the quartz substrate, the amount of the residual gas (He) incorporated is gradually reduced. As the passage of He through the quartz substrate takes time, it is more preferable to employ a depressurized He atmosphere. The depressurized atmosphere is preferably 1 kPa to 90 kPa and particularly preferably 1 kPa to 10 kPa.

Both the mold and the substrate to which the resist solution is applied are aligned so as to have a predetermined relative positional relationship and then the mold is brought into contact with the substrate. For the alignment, an alignment mark is preferably used.

The pressing force of the mold is within a range of 100 kPa or more and 10 MPa or less. A high pressure promotes the flow of the resist solution, also promotes the compression of the residual gas, dissolution of the residual gas in the resist and the passage of He through the quartz substrate, and leads to improvement in the residual gas removal rate. However, when the applied pressure is too strong, there is a possibility that foreign matter may enter between the mold and the substrate when the mold is brought into contact with the substrate, and the mold and the substrate may be damaged. Accordingly, the pressing force of the mold is preferably 100 kPa or more and 10 MPa or less, more preferably 100 kPa or more and 5 MPa or less, and even more preferably 100 kPa or more and 1 MPa or less. The reason why the pressing force is set to a value of 100 kPa or more is that in the case in which the space between the mold and substrate is filled with liquid, the space between the mold and substrate is pressurized under atmospheric pressure (about 101 kPa) when imprinting is performed in the atmosphere.

<Curing Process of Curing Resist Solution>

After the resist film is formed by pressing the mold, the resist is exposed to light having a wavelength according to the photopolymerization initiator included in the resist solution and cured.

<Release Process of Releasing Mold from Cured Resist Film>

The mold 1 is separated (released) from the cured resist film. As the release method, a method of, in a state in which one rear surface or one outer edge portion of the mold or the substrate is held and the other rear surface or the other outer edge portion thereof is held, relatively moving the portion in which the outer edge is held or the portion in which the rear surface is held is in a direction opposite to the direction of the pressure application.

(Etching Treatment)

The substrate on which the resist pattern 35 is formed by the nanoimprinting method as described above is subjected to an etching treatment by the etching method of the present invention.

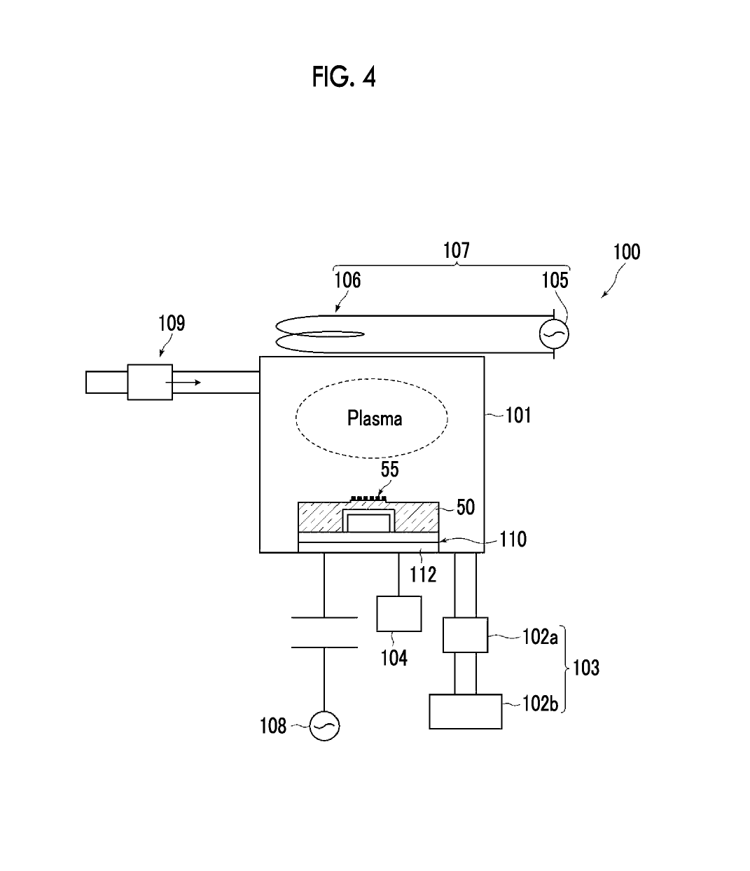

FIG. 4 is a schematic view showing a schematic configuration of an embodiment of an etching apparatus 100 for implementing the etching method of the present invention.

The etching apparatus 100 has a treatment container (chamber) 101 capable of maintaining an atmosphere reduced in pressure compared to atmospheric pressure, a pressure reducing portion 103 including a pressure adjusting portion 102a for reducing the pressure of the inside of the treatment container 101 to a predetermined pressure and an exhaust system 102b such as a vacuum pump, a substrate mounting structure portion 110 provided in the treatment container 101 for mounting a dielectric substrate 50, which is a substrate to be processed, and supporting and fixing the dielectric substrate 50, and a plasma generating portion 107 for generating plasma including a high frequency power supply 105 and a plasma generating antenna 106.

The substrate mounting structure portion 110 includes the lower electrode 112 and the apparatus 100 is provided with a bias power supply 108 for applying a bias pressure to the lower electrode 112. In addition, the substrate mounting structure portion includes a temperature adjustor 104 which controls the temperature of the substrate mounting structure portion 110, and a gas inlet 109 provided with a gas flow rate controller for introducing a desired amount of gas into the treatment container 101.

The etching carried out by the apparatus 100 is preferably reactive ion etching (RIE) and particularly, as a mechanism for generating plasma, inductively coupled plasma (ICP)-RIE, capacitively coupled plasma (CCP)-RIE, or electron cyclotron resonance (ECR)-RIE is preferable. In the embodiement, a method capable of controlling the bias power (power for forming a bias between the plasma and the lower electrode) independent of the plasma power (power for forming plasma) is adopted in order to facilitate the control of the bias power.

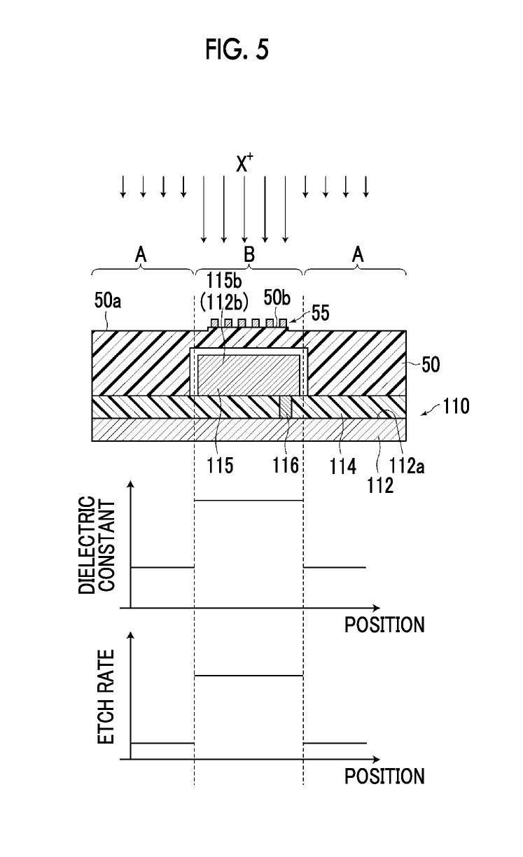

The following three etching treatments are carried out on the template substrate on which the resist pattern 35 is formed using such an etching apparatus 100. Each etching treatment corresponds to one embodiement of the etching method of the present invention. That is, each etching treatment is a method of carrying out etching on the dielectric substrate composed of the pattern area B in which the resist pattern is formed and the non-pattern area A in which the resist pattern is not formed. In each etching treatment, as shown in FIG. 5, in the case in which the dielectric substrate 50 is mounted at a predetermined position on the substrate mounting structure portion 110 including the predetermined electrode (substrate lower electrode) 112 in the treatment container 101 of the etching apparatus, the dielectric substrate is etched by setting the configuration of the substrate mounting structure portion 110 such that the average dielectric constant between the surface 50b of the dielectric substrate 50 and the surface 112a of the predetermined electrode 112 of the substrate mounting structure portion 110 in the pattern area B is larger than the average dielectric constant between the surface 50a of the dielectric substrate and the surface 112a of the predetermined electrode 112 of the substrate mounting structure portion 110 in the non-pattern area A, mounting the dielectric substrate 50 at the predetermined position on the substrate mounting structure portion 110, and generating plasma under an atmosphere reduced in pressure compared to atmospheric pressure.

FIG. 5 shows graphs of the dielectric constant between the surface of the substrate and the surface of the lower electrode in the plane direction of the substrate, and the etching rate (etch rate) thereof. As shown in FIG. 5, the etching rate is proportional to the dielectric constant between the lower electrode and the surface of the substrate, and as the dielectric constant increases, the etching rate increases. That is, by setting the average dielectric constant of the pattern area B to be larger than the average dielectric constant of the non-pattern area A so that the etching rate of the pattern area B can be made higher than the etching rate of the non-pattern area A. Accordingly, it is possible to inhibit the production of the etching product in the non-pattern area A and thus pattern non-uniformity caused by the etching product generated in the non-pattern area A and the generation of a defective pattern can be inhibited.

In a first configuration example shown in FIG. 5, the substrate mounting structure portion 110 includes the substrate lower electrode (herein, a negative electrode) 112 and a substrate mounting portion 114 provided thereon, and an auxiliary member 115 composed of a conductor arranged at the center portion of the substrate mounting portion 114 so as to backfill the counterbore portion 51 of the dielectric substrate, and the auxiliary member 115 is configured to be electrically connected to the lower electrode 112 by the conductive connection portion 116. Since the surface 115b of the auxiliary member 115 is a surface facing the rear surface of the substrate 50 and the auxiliary member 115 is electrically connected to the lower electrode 112 by the conductive connection portion 116, the potential of the auxiliary member is equal to the potential of the lower electrode 112. Accordingly, in the pattern area B, the surface 115b of the auxiliary member 115 corresponds to the surface 112b of the lower electrode 112.

The substrate 50 to be process, which is an object to be processed in the present invention, may be a single layer or a layered body. However, the substrate is formed from the dielectric and is not provided with a conductive film extending over the pattern area and the non-pattern area. When the substrate 50 to be process is a conductor or is provided with a conductive film over the both areas, the substrate has the equipotential over the entire surface area and thus an effect of enhancing the etching rate of only the pattern area cannot be obtained.

(1) Remaining Film Etching

A remaining film etching process is a process for removing the residual resist film formed on the bottom of the recessed portion when the resist pattern is formed by the nanoimprinting method. Examples of an etching gas include oxygen gas, argon gas, and fluorocarbon gas. Herein, a layered body of the substrate 10, the hard mask layer 20, and the residual resist film corresponds to the dielectric substrate 50 in the etching method of the present invention and the resist pattern 35 corresponds to the mask pattern 55.

(2) Hard Mask Layer Etching

The etching process of the hard mask layer 20 is a process for forming the hard mask pattern 25 by removing the hard mask layer 20 exposed to the recessed portion using the resist pattern 35 as a mask. Similar to the aforementioned remaining film etching, reactive ion etching (RIE) is preferably used and particularly, inductively coupled plasma (ICP)-RIE, capacitively coupled plasma (CCP)-RIE, or electron cyclotron resonance (ECR)-RIE is preferable. Further, in the present invention, a method capable of control the bias power (power for forming a bias between the plasma and the electrode (lower electrode) of the substrate mounting portion side) independent of the plasma power (power for forming plasma) is preferably adopted in order to facilitate the control thereof. The etching conditions for the reactive ion etching when the hard mask layer is etched are selected such that the etching selectivity of the hard mask layer with respect to the resist is high (herein, the selectivity is defined as selectivity=mask layer etching rate/resist etching rate). This is because as the selectivity is low, the resist mask is partially eliminated and breaking (disconnection) defects occur. In addition, in the process, at least a bias voltage is applied. This is because if a bias voltage is not applied, etching is not anisotropically carried out. If a bias is not applied, etching is not anisotropically carried out and a significant CD shift (an increase in CD) cannot be avoided.

Herein, the layered body of the substrate 10 and the hard mask layer 20 corresponds to the dielectric substrate 50 in the etching method of the present invention and the resist pattern 35 corresponds to the mask pattern 55.

(3) Substrate Etching

The substrate etching process is a process for etching the substrate 10 using the hard mask pattern 25 as a mask. Similar to the aforementioned remaining film etching and hard mask layer etching, reactive ion etching (RIE) is preferably used and particularly, inductively coupled plasma (ICP)-RIE, capacitively coupled plasma (CCP)-RIE, or electron cyclotron resonance (ECR)-RIE is preferable. Examples of an etching gas to be used include, in the case of using quartz for a substrate, CHF₃, CF₄, SF₆, and Ar. Herein, the substrate 10 corresponds to the dielectric substrate 50 in the etching method of the present invention and the hard mask pattern 25 corresponds to the mask pattern 55.

Through the above etching processes, an uneven pattern corresponding to the resist pattern 35 is formed on the surface of the template substrate 10 and thus an uneven patterned substrate can be obtained.

The configuration of the substrate mounting structure portion 110 can be set such that the etching rate in the pattern area is higher than the etching rate in the non-pattern area according to the shape of the dielectric substrate which is an object to be etched. Decreasing the etching rate of the non-pattern area and increasing the etching rate of the pattern area lead to inhibition of non-uniformity in the shape of the projecting portion of the forming pattern and pattern defects generated by contamination. When the average dielectric constant between the surface of the lower electrode and the surface of the substrate in the pattern area is set to be larger than the average dielectric constant between the surface of the lower electrode and the surface of the substrate in the non-pattern area, the etching rate in the pattern area can be made higher than the etching rate in the in the non-pattern area. Specifically, the etching rate can be adjusted by arranging a high dielectric constant material, or an auxiliary member composed of a conductor below the pattern area and arranging a low dielectric constant material (or forming a free space) in the non-pattern area. The dielectric constant between the surface of the substrate and the surface of the lower electrode can be controlled by adjusting any one of, or a combination of the thickness of the dielectric auxiliary member, a gap distance of the free space (a distance between the surface of the auxiliary member and the surface of the substrate), and a distance between the surface of the substrate and the surface of the lower electrode.

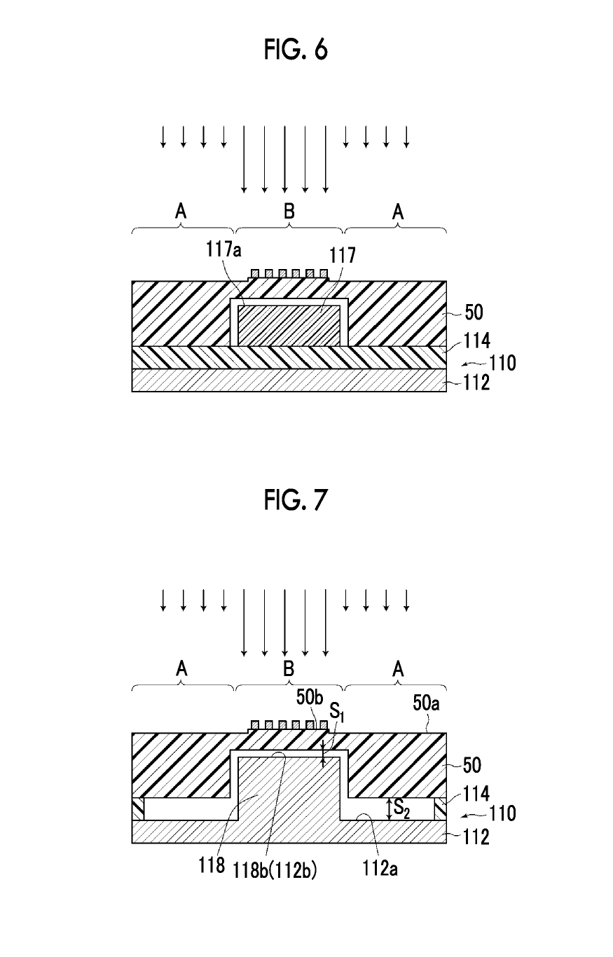

Hereinafter, various embodiments of the substrate mounting structure portion 110 will be described with reference to FIGS. 6 to 16. FIGS. 6 to 16 are schematic views showing various embodiments of the substrate mounting structure portion 110. In the following description, the same reference numerals will be assigned to the same components and the detailed description thereof will be omitted.

In a second configuration example shown in FIG. 6, the configuration of the substrate mounting structure portion 110 is set to include the substrate lower electrode 112, the substrate mounting portion 114 provided thereon, and an auxiliary member 117 having a dielectric constant higher than the dielectric constant of the substrate 50, which is provided at the center portion of the substrate mounting portion 114 to backfill the counterbore portion 51 of the dielectric substrate 50. The auxiliary member 117 having a high dielectric constant is arranged and formed so that the surface 117a thereof faces the rear surface of the substrate 50 in parallel so as to almost fill the counterbore portion of the substrate 50. Accordingly, the average dielectric constant of the lower portion of the pattern area B is larger than the average dielectric constant of the lower portion of the non-pattern area A.

In a third configuration example shown in FIG. 7, the substrate mounting structure portion 110 is configured to include the substrate lower electrode 112 provided with a projecting portion 118 in an area corresponding to the counterbore portion 51 of the dielectric substrate 50, and the substrate mounting portion 114 which is erected on the peripheral edge portion of the electrode 112 which supports the dielectric substrate 50 at the peripheral edge thereof. The projecting portion 118 is integrally formed with the electrode 112 by using the same material as the electrode. The distance between the electrode surface 112b and the surface 50b of the substrate is reduced in the pattern area B and the height of the projecting portion 118 and the height of the substrate mounting portion 114 are set such that the dielectric constant in the pattern area B is larger than the dielectric constant in the non-pattern area A by adjusting a distance S₁ between the projecting portion surface 118b and the rear surface of the substrate 50 and a distance S₂ between the electrode surface 112a and the rear surface of the substrate in the non-pattern area A, respectively.

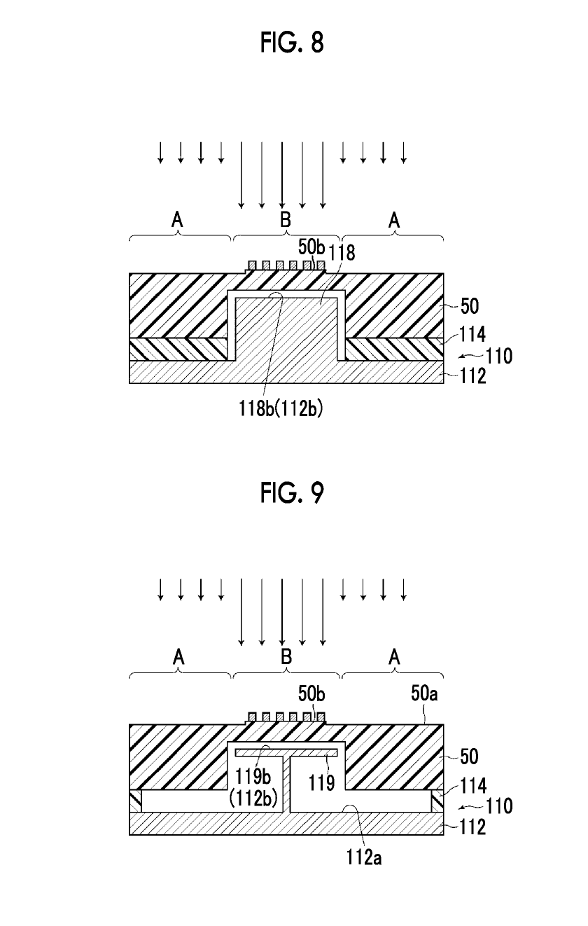

In a fourth configuration example shown in FIG. 8, the substrate mounting structure portion 110 is configured to include the substrate lower electrode 112 provided with the projecting portion 118 in an area corresponding to the counterbore portion 51 of the dielectric substrate 50, and the substrate mounting portion 114 which supports the dielectric substrate 50 at the lower surface of the non-pattern area A and is formed so as to surround the projecting portion. The dielectric constant between the electrode surface 112b and the surface 55a of the substrate is larger than the dielectric constant in the non-pattern area A by reducing a distance between the electrode surface 112b and the surface 50b of the substrate in the pattern area B.

In a fifth configuration example shown in FIG. 9, the substrate mounting structure portion 110 is configured to include the substrate lower electrode 112 provided with an auxiliary member 119 having a T-shaped cross section which is provided in the area corresponding to the counterbore portion 51 of the dielectric substrate 50, and the substrate mounting portion 114 which is erected on the peripheral edge portion of the electrode 112 and supports the dielectric substrate 50 at the peripheral edge thereof. Similar to the third configuration example shown in FIG. 7, the auxiliary member 119 is integrally formed with the lower electrode as a part of the lower electrode 112, a surface 119b of the auxiliary member 119 in an area corresponding to the counterbore portion is a surface facing the rear surface of the substrate in parallel, and the auxiliary member constitutes the electrode surface 112b of the lower electrode 112. Thus, a distance between the electrode surface 112b and the surface 50b of the substrate in the pattern area B can be reduced. A distance Sᵢ between the auxiliary member surface 119b and the rear surface of the substrate and a distance S₂ between the electrode surface 112a and the rear surface of the substrate in the non-pattern area A are set such that the dielectric constant in the pattern area B is larger than the dielectric constant in the non-pattern area A by adjusting the height of the auxiliary member surface 119b and the height of the substrate mounting portion 114.

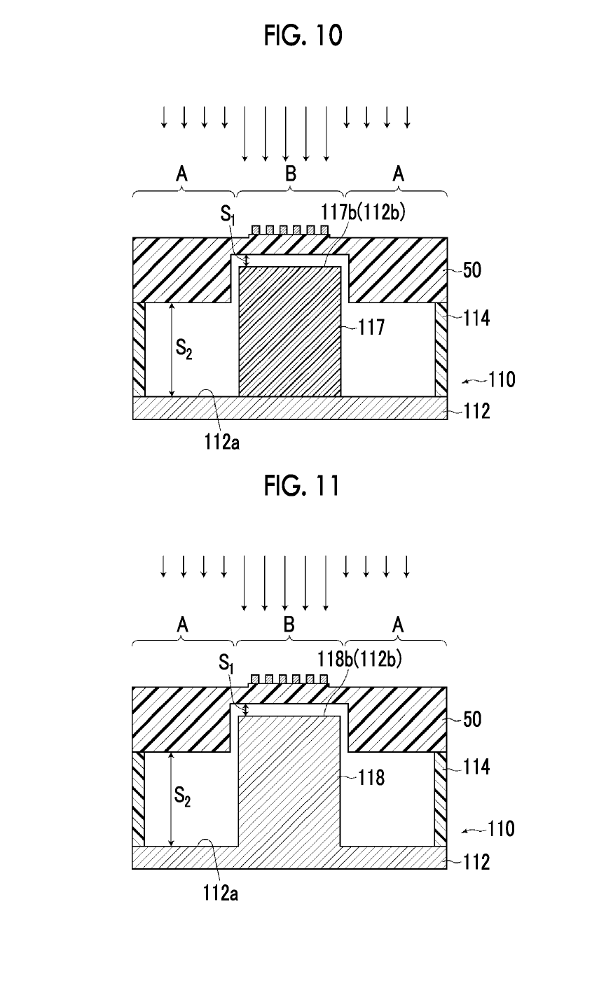

In a sixth configuration example shown in FIG. 10, similar to the second configuration example shown in FIG. 6, the substrate mounting structure portion 110 includes the auxiliary member 117 having a dielectric constant higher than the dielectric constant of the substrate 50 in the area corresponding to the counterbore portion 51 of the dielectric substrate 50. In addition, the substrate mounting portion 114 which supports the dielectric substrate 50 at the peripheral edge thereof and is erected on the peripheral edge portion of the substrate lower electrode 112. A distance Sᵢ between an auxiliary member surface 117b and the rear surface of the substrate and a distance S₂ between the electrode surface 112a and the rear surface of the substrate in the non-pattern area A are respectively set according to the height of the auxiliary member 117 and the height of the substrate mounting portion 114 such that the dielectric constant in the pattern area B is larger than the dielectric constant in the non-pattern area A.

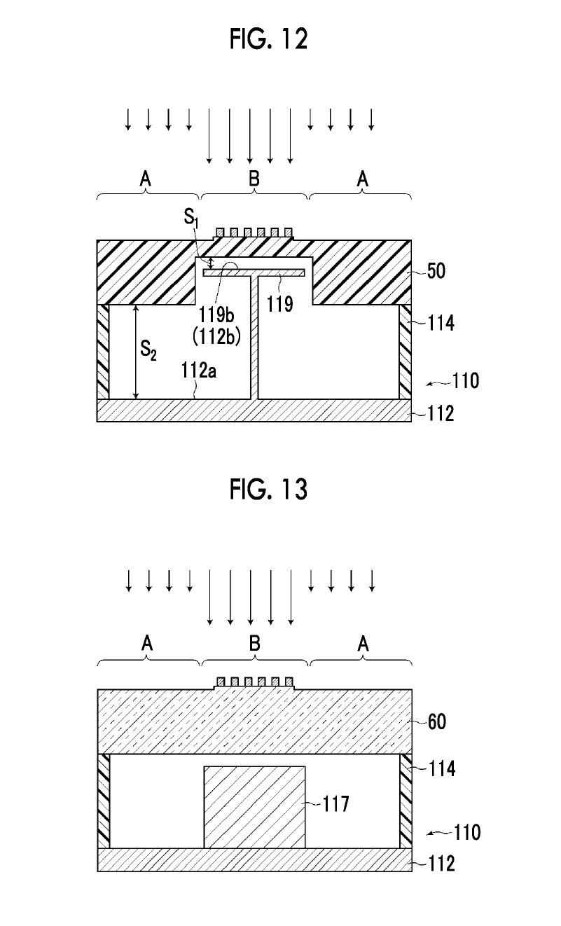

A seventh configuration example shown in FIG. 11 and an eighth configuration example shown in FIG. 12 have almost the same configurations as the third configuration example shown in FIG. 7 and the fifth configuration example shown in FIG. 9, respectively. However, the etching rate is adjusted by increasing a difference between a distance Sᵢ between the electrode surface 112b and the rear surface of the substrate 50 in the pattern area B and a distance S₂ between the electrode surface 112a and the rear surface of the substrate in the non-pattern area A.

In the above examples, in any case, the dielectric substrate 50 has the counterbore portion at the center portion but the shape of the dielectric substrate 50 which is an object to be etched in the present invention may be a substrate which does not have a counterbore portion. In FIGS. 13 to 15, the configuration examples of the substrate mounting structure portion 110 used in the case of using a dielectric substrate 60 which does not have counterbore portion and whose rear surface is flat as a substrate to be processed are shown. Herein, the substrate 60 also has a pedestal portion at the center portion of the surface but may have a flat surface which does not have this pedestal portion.

In a ninth configuration example shown in FIG. 13, the substrate mounting structure portion 110 is configured to include the substrate lower electrode 112, the auxiliary member 117 arranged in the area corresponding to the pattern area B of the dielectric substrate 60 on the lower electrode 112, and the substrate mounting portion 114 which supports the dielectric substrate 60 at the peripheral edge thereof and is erected on the peripheral edge portion of the electrode 112. The auxiliary member 117 is composed of a high dielectric constant material having a dielectric constant higher than that of a free space. The configuration of the substrate mounting structure portion is set such that the dielectric constant in the pattern area B is larger than the dielectric constant in the non-pattern area A by providing the auxiliary member 117 having a high dielectric constant in the pattern area B and adjusting the height of the auxiliary member 117 and the height of the substrate mounting portion 114.

In the same configuration, instead of using the auxiliary member 117 having a high dielectric constant, an auxiliary member composed of a conductive material may be provided.

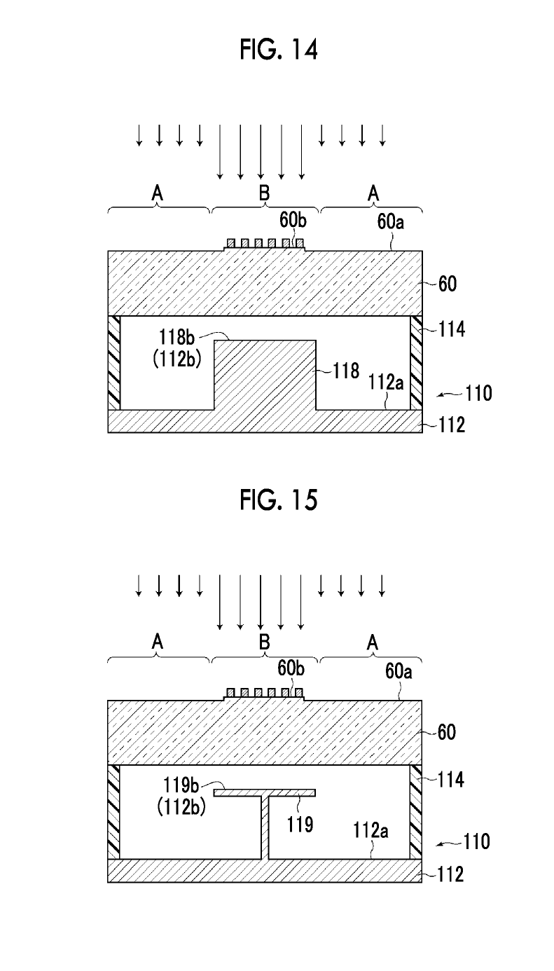

A tenth configuration example shown in FIG. 14 has the same configuration as the third configuration example shown in FIG. 7, and the substrate mounting structure portion 110 is configured to include the substrate lower electrode 112 provided with the projecting portion 118 in the area corresponding to the pattern area B of the dielectric substrate 60, and the substrate mounting portion 114 which supports the dielectric substrate 60 at the peripheral edge thereof and is erected on the peripheral edge portion of the electrode 112. The projecting portion 118 is integrally formed with the electrode by using the same material as the electrode 112. The configuration of the substrate mounting structure portion is set such that the dielectric constant in the pattern area B is larger than the dielectric constant in the non-pattern area A by making a distance between the electrode surface 112b and a surface 60b of the substrate in the pattern area B shorter than a distance between the electrode surface 112a and a surface 60a of the substrate in the non-pattern area A and adjusting the height of the projecting portion 118 and the height of the substrate mounting portion 114.

An eleventh configuration example shown in FIG. 15 has the same configuration as the fifth configuration example shown in FIG. 9, and the substrate mounting structure portion 110 is configured to include the substrate lower electrode 112 provided with an auxiliary member 119 having a T-shaped cross section in area corresponding to the pattern area B of the dielectric substrate 60, and the substrate mounting portion 114 which is erected on the peripheral edge portion of the electrode 112 and supports the dielectric substrate 60 at the at the peripheral edge thereof. The auxiliary member 119 is integrally formed with the lower electrode and constitutes a part of the electrode. The surface 119b thereof constitutes the electrode surface 112b facing the rear surface of the substrate 60 in parallel and is provided to reduce the distance between the electrode surface 112b and the surface 60b of the substrate in the pattern area B. The configuration of the substrate mounting structure portion is set such that the dielectric constant in the pattern area B is larger than the dielectric constant in the non-pattern area A by adjusting the height to the surface of the auxiliary member and the height of the substrate mounting portion 114.

In the above, a plurality of examples for the substrate mounting structure portion 110 are mentioned and described. However, in the etching method of the present invention, as long as the average dielectric constant between the surface of the dielectric substrate and the surface of the lower electrode in the pattern area B is larger than the average dielectric constant between the surface of the dielectric substrate and the surface of the lower electrode in the non-pattern area A, there is no particular limitation.

### EXAMPLES

Hereinafter, Examples and Comparative Examples of the present invention will be described.

### Example 1

First, Example 1 in which a patterned substrate is manufactured using the etching method of the present invention will be described.

(Production of Master Template (Mold))

A resist solution having a polyhydroxy styrene (PHS) chemical amplification resist or the like as a main component was applied to a Si substrate by spin coating to form a resist layer. Then, while scanning the Si substrate on an XY stage, the substrate was irradiated with an electron beam and the resist layer was subjected to exposure for a desired pattern in a range of 25 mm×31 mm square. Subsequently, the resist layer underwent a development process and the exposed portion was removed to form a resist pattern. Selective etching was carried out using the resist pattern as a mask by RIE to form a groove-shaped line pattern having a width of 28 nm, a pitch of 56 nm, and a depth of 60 nm, as an uneven pattern. Thus, a Si master template was obtained. At this time, the taper angle of the groove of the Si master template was 86° . The surface of the mold underwent a release treatment with OPTOOL (registered trademark) DSX by a dip coating method.

(Nanoimprinting Substrate)

As a nanoimprinting substrate, a substrate, which is a quartz substrate having a size of 152 mm square and a thickness of 6.35 mm, in which a pedestal shape having a size of 26 mm×32 mm square and a height of 30 μm was formed at the substrate center portion of the quartz substrate as an area to be transferred by wet etching, and the substrate center portion was subjected to processing for a counterbore (recessed portion) having a diameter of 64 mm and a depth of 5 mm, was used. When an etching mask layer (hard mask layer) was applied to the surface of the substrate, a CrOₓN_{y} film having a thickness of 4 nm was formed by reactive ion sputtering. Then, the surface of the substrate was treated with KBM-5103 (manufactured by Shin-Etsu Chemical Co., Ltd.) as a silane coupling agent having excellent adhesiveness with the resist. Specifically, KBM-5103 was diluted to 1% by mass using propylene glycol-1-monomethyl ether-2-acetate (PGMEA) and applied to the surface of the substrate by a spin coating method. Subsequently, the coated substrate was annealed on a hot plate under conditions of 150° C. for 5 minutes, and the silane coupling agent was bonded to the surface of the substrate.

(Resist Pattern Forming Process)

Herein, a resist pattern was formed by the nanoimprinting method.

First, a resist solution containing 48 w % of the aforementioned compound A, 48 w % of ARONIX (registered trademark) M-220, 3 w % of IRGACURE (registered trademark) 379, and 1 w % of the aforementioned compound B was prepared. This resist solution was applied to the CrOₓN_{y} film of the quartz substrate. DMP-2838, which is an ink jet printer of the piezoelectric type by FUJIFILM DIMATIX, was used for the application of the resist solution. DMC-11610, which is a dedicated 10 pl (picoliters) head, was used as an ink jet head. Ink jetting conditions were set and adjusted in advance such that the amount of liquid droplets was about 10 pl. The liquid droplet arrangement pattern was set to a lattice pattern with a pitch of 450 μm. Liquid droplets were arranged in the transfer area (on the substrate pedestal) according to the liquid droplet arrangement pattern.

Next, the mold and the quartz substrate were made to be close to the position at which the gap between the mold and the quartz substrate was 0.1 mm or less and the mold and the quartz substrate were aligned such that the alignment mark on the substrate from the back surface of the quartz substrate matched with the alignment mark on the mold. 99 volume % or more of the space between the mold and the quartz substrate was purged with He gas and after purging with He, the pressure was reduced to 50 Pa or less. Under the reduced He condition, the mold was brought into contact with the liquid droplets composed of the resist. After the mold was brought into contact with the liquid droplets, a pressing force of 1 MPa was applied for 5 seconds and then exposure was carried out by ultraviolet light including a wavelength of 360 nm with an irradiation dose of 300 mJ/cm² to cure the resist. Then, the mold was released from the substrate.

<Configuration of Substrate Mounting Structure Portion of Etching Apparatus>

As the configuration of the substrate mounting structure portion in the etching apparatus, the configuration shown in FIG. 7 was adopted.

Both etching and ashing below were carried out with an inductively coupled plasma (ICP) reactive ion etching apparatus provided with the substrate mounting structure portion shown in FIG. 7. In FIG. 7, the distance S₁ between the projecting surface of the lower electrode and the rear surface of the substrate was 1 mm and the distance S₂ between the surface of the lower electrode and the rear surface of the substrate in the non-pattern area was 3 mm.

After the resist pattern was formed by the nanoimprinting method, the following etching and ashing were carried out sequentially.

<Remaining Film Etching>

First, remaining film etching was carried out under the etching conditions shown below to remove the resist film remaining in the recessed portion after the resist pattern was formed by the nanoimprinting method.

Type of gas: oxygen: argon=2:1

Process pressure: 1 Pa

ICP power: 100 W

Bias power: 50 W

Amount of overetching: 50%

<Hard Mask Layer Etching>

Next, hard mask layer etching was carried out using the resist pattern as a mask under the etching conditions shown below to form a hard mask pattern.

Type of gas: chlorine:oxygen=3:1

Process pressure: 5 Pa

ICP power: 100 W

Bias power: 5 W

Amount of overetching: 50%

<Substrate (quartz) Etching>

Next, substrate (quartz) etching was carried out using the resist pattern as a mask under the etching conditions shown below.

Type of gas: CHF₃:CF₄:Ar=3:1:10

Process pressure: 3 Pa

ICP power: 75 W

Bias power: 75 W

Target depth: 60 nm

Further, ashing and hard mask removal were respectively sequentially carried out under the conditions shown below.

<Ashing>

Type of gas: oxygen: argon=2:1

Process pressure: 1 Pa

ICP power: 100 W

Bias power: 0 W

<Mask Removal>

Type of gas: chlorine: oxygen=3:1

Process pressure: 5 Pa

ICP power: 100 W

Bias power: 0 W

The four types of etching processes (including ashing) were carried out in the separate chambers, respectively. That is, four chambers for remaining film etching, hard mask etching, substrate (quartz) etching, and ashing and mask removal were prepared.

Through the above procedure, an uneven pattern was formed on the surface of the quartz substrate and thus a patterned substrate was obtained.

### Comparative Example 1

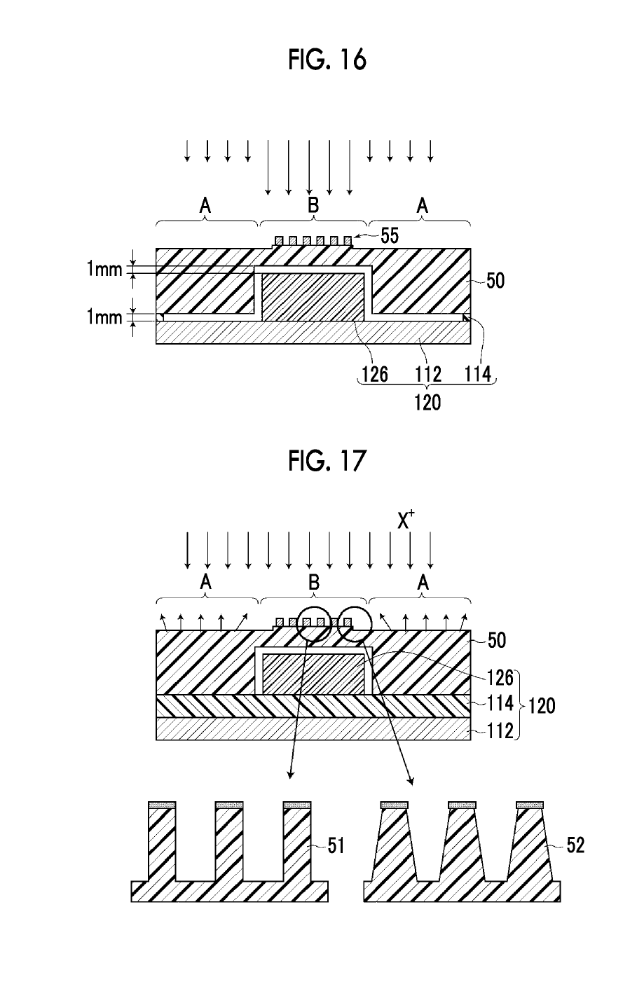

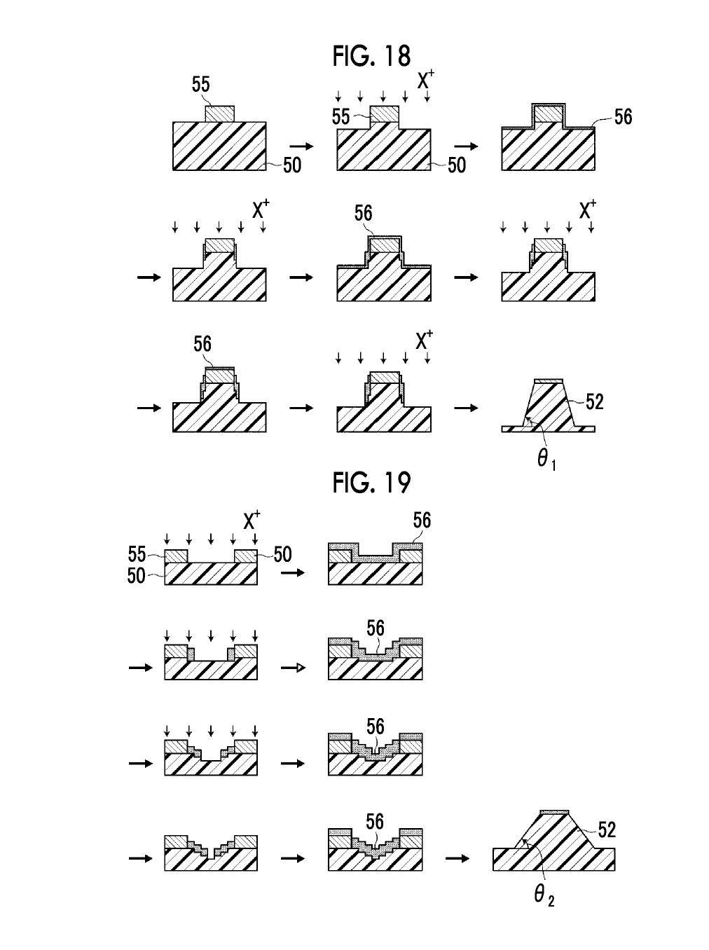

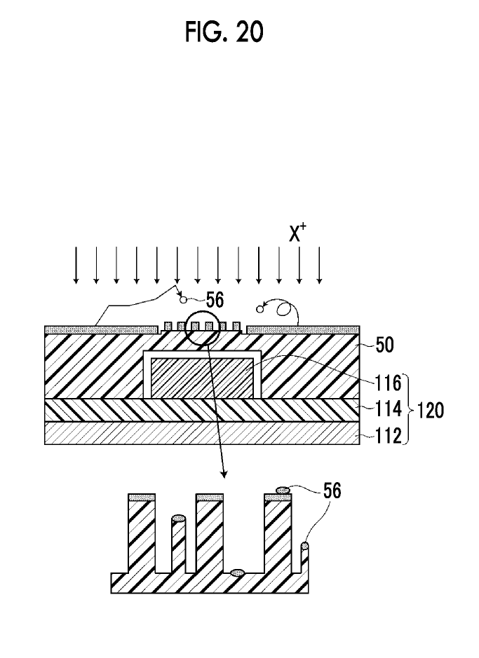

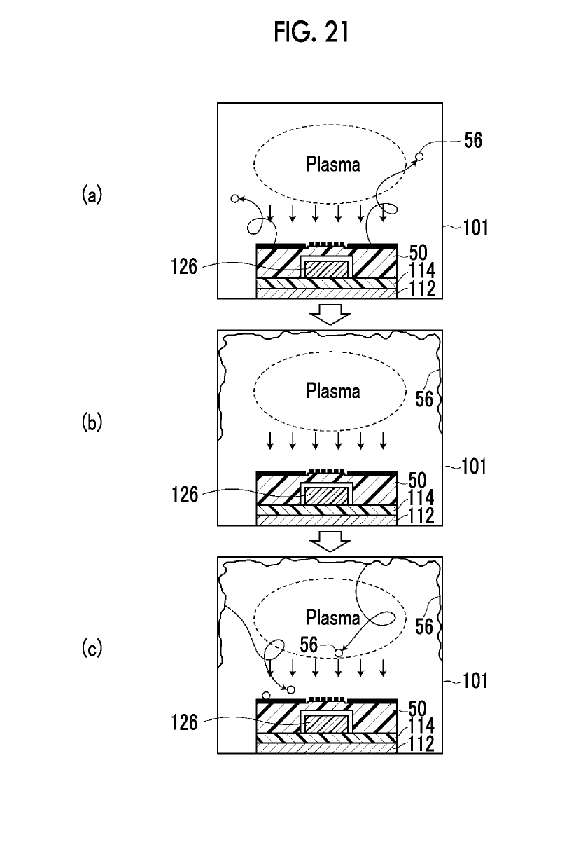

As the configuration of the substrate mounting structure portion of the etching apparatus, the configuration shown in FIG. 16 was used. A substrate mounting structure portion 120 shown in FIG. 16 is provided with an auxiliary member 126 composed of the same material as the substrate 50 (quartz, herein) in the area corresponding to the pattern area B on the lower electrode 112 (the area corresponding to the counterbore portion). The substrate mounting structure portion was configured such that both a distance between the surface of the auxiliary member 126 and the rear surface of the substrate 50 and a distance between the surface of the lower electrode and the rear surface of the substrate 50 in the non-pattern area were 1 mm. According to the configuration, the electrostatic capacity between the surface of the substrate and the substrate lower electrode are almost the same in the pattern area B and in the non-pattern area A. A patterned substrate was formed on in the same procedure as in Example 1 except that this apparatus was used.

Example 1 and Comparative Example 1 were evaluated as follows.

(Pattern Shape Evaluation)

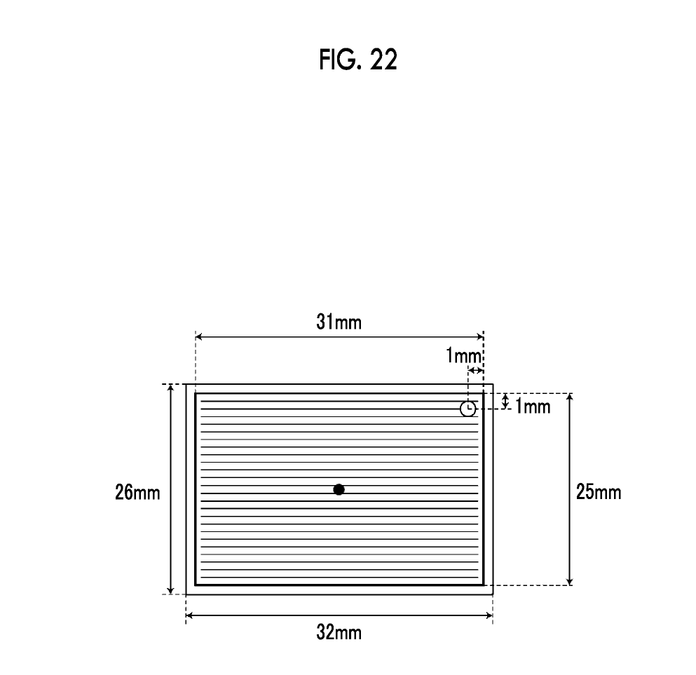

For the patter shape evaluation, the side wall angles of two points from a point of the pattern at the center portion of the pedestal and points 1 nm inside from the four corners of the pattern in the respective major and minor length directions of the pattern area were evaluated for comparison. FIG. 22 is a plan view schematically showing the pedestal portion formed in the pattern area. A pattern area having a size of 25 mm×31 mm is formed inside the pedestal portion having a size of 26 mm×32 mm. A plurality of linear projecting portions are formed in the pattern area. The side wall angles of the black circle mark approximately at the center portion of the pattern area and white circle mark 1 mm inside from one corner of the pattern area vertically and horizontally were respectively measured and a difference between the both angles was calculated.

Each side wall angle was obtained by etching the substrate in a direction orthogonal to the line pattern by a focused ion beam method and cutting the pattern cross section, then obtaining the electron microscopy image of the pattern cross section using a transmission electron microscope, and calculating the side wall angle from the obtained electron microscopy image.

(Evaluation Result)

In Example 1, the difference in the side wall angle between the center portion and the corner portion was 0.8 degrees. On the other hand, in Comparative Example 1, the difference in the side wall angle between the center portion and the corner portion was 3.8 degrees. That is, the difference in the side wall angle between the center portion and the end portion of the pattern area in Example 1 was smaller than the difference in the side wall angle between the center portion and the end portion in Comparative Example 1, and the superiority of the present invention regarding in-plane uniformity in the etching shape (side wall angle) to the related art was proved.

Next, an increase in the generation of defects due to repeatedly carrying out the treatments was verified.

### Example 2

When the aforementioned treatment in Example 1 was continuously carried out on 250 substrates, an amount of increase in defect density (increased defect density) of each of the first substrate and the 250^{th} substrate before and after the etching process was measured and the difference in the increased defect density was calculated.

Specifically, the defect density DD (Defect Density/cm²) was obtained by counting the number of defects by observing the entire pattern area of the substrate with CD-SEM, before the fourth etching process (that is, before the remaining film etching) and after the fourth etching process (that is, after the ashing and mask removal). Subsequently, the difference in the defect density before and after the etching process was obtained and the increased defect density in the etching process was calculated.

### Comparative Example 2

The increased defect density was calculated in the same manner by carrying out the same treatment as in Example 2 except that the aforementioned treatment of Comparative Example 1 was continuously carried out instead of the treatment of Example 1.

(Evaluation Result)

The difference in the increased DD before and after 250 times of etching processes (250^{th} increased DD—first increased DD) was 35.3/cm² in Example 2 and the difference in the increased DD before and after 250 times of etching processes was 395.1/cm² in Comparative Example 2. That is, the difference in the increased DD in Example 2 was much smaller that the difference in the increased DD in Comparative Example 2 and when the etching method used in Examples was used, it was proved that contamination of the etching apparatus was inhibited and thus the generation of defects was inhibited.

What is claimed is:

1. A plasma etching method of carrying out plasma etching on a dielectric substrate provided with a mask pattern on a surface side, the method comprising:
when the mask pattern provided on the dielectric substrate includes a pattern area having a plurality of micro openings and a non-pattern area other than the pattern area,
in a case in which the dielectric substrate is mounted at a predetermined position in a substrate mounting structure portion including a predetermined electrode in a plasma etching apparatus, setting a configuration of the substrate mounting structure portion such that an average dielectric constant between the surface of the dielectric substrate and a surface of the predetermined electrode of the substrate mounting structure portion in the pattern area is larger than the average dielectric constant in the non-pattern area;
mounting the dielectric substrate at the predetermined position on the substrate mounting structure portion; and
generating plasma under an atmosphere reduced in pressure compared with atmospheric pressure to etch the dielectric substrate.

2. The plasma etching method according to claim 1,
wherein the configuration of the substrate mounting structure portion is set such that a distance between the surface of the dielectric substrate and the surface of the predetermined electrode in the pattern area is shorter than the distance in the non-pattern area.

3. The plasma etching method according to claim 1,
wherein the configuration of the substrate mounting structure portion is set such that the volume of a free space between the surface of the dielectric substrate and the surface of the predetermined electrode in the pattern area is smaller than the volume of the free space in the non-pattern area.

4. The plasma etching method according to claim 1,
wherein a mask material for the mask pattern is a nonconductor.

5. The plasma etching method according to claim 1,
wherein the dielectric substrate is a substrate having a counterbore portion at the center portion of a rear surface, and
the mask pattern has the pattern area in at least a part of an area corresponding to the counterbore portion of the dielectric substrate, and an area not corresponding to the counterbore portion of the dielectric substrate is the non-pattern area.

6. A method of manufacturing a patterned substrate comprising:
sequentially depositing a hard mask layer and applying a resist layer on a surface of a dielectric substrate;
forming a plurality of micro openings on the resist layer to form a resist pattern;
etching the hard mask layer using the resist pattern as a mask to form a hard mask pattern; and
etching the dielectric substrate using the hard mask pattern as a mask to manufacture a patterned substrate,
wherein the plasma etching method according to claim 1 is used during the etching of the hard mask layer and/or the etching of the dielectric substrate.
